(19) United States
(12) Patent Application Publication
(10) Pub. No.: US 2010/0027351 A1
(43) Pub. Date: Feb. 4, 2010

(54) Memory device and memory programming method

(75) Inventor: Kwang Soo Seol, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 12/382,035

(22) Filed: Mar. 6, 2009

(30) Foreign Application Priority Data
Aug. 1, 2008 (KR) 10-2008-0075559

(51) Int. Cl. G11C 16/04; G06F 12/00; G06F 12/02

(52) U.S. Cl. 365/185.24; 711/103; 711/E12.001; 711/E12.008

(57) ABSTRACT

A memory device and a memory programming method are provided. The memory device may program data in a multi-level cell (MLC) or a multi-bit cell (MBC) memory device. The memory device may include a memory cell array, a programming unit and a program level stabilization unit. The memory cell array may include a plurality of multi-level cells. The programming unit may be configured to program a first data page in the plurality of multi-level cells and to program a second data page in the plurality of multi-level cells having the programmed first data page. The program level stabilization unit may be configured to stabilize a program level of at least one of the first data page and the second data page.

### PRIORITY STATEMENT

This application claims priority under 35 U.S.C. §119 to Korean Patent Application No. 10-2008-0075559, filed on Aug. 1, 2008, in the Korean Intellectual Property Office (KIPO), the entire contents of which are incorporated herein by reference.

### BACKGROUND

1. Field

Example embodiments relate to apparatuses and methods that may program data in a memory device. Also, example embodiments relate to apparatuses and methods that may program data in a multi-level cell (MLC) or a multi-bit cell (MBC) memory device.

2. Description of the Related Art

A single-level cell (SLC) memory device may store one bit of data in a single memory cell. The SLC memory may be referred to as a single-bit cell (SBC) memory. A process of storing one bit of data in a single level cell of the SLC memory device may be referred to as a programming process and may change a threshold voltage of the single level cell. For example, when data of logic value “1” is stored in a single level cell, the single level cell may have a threshold voltage of 1.0 V. When data of logic value “0” is stored in the single level cell, the single level cell may have a threshold voltage of 3.0 V.

Due to a minute electrical characteristic difference between single level cells, the threshold voltage formed in each of the single level cells with the same data programmed may have a distribution within a predetermined range. For example, when a voltage read from a memory cell is greater than 0.5 V and less than 1.5 V, it may be determined that data stored in the memory cell has a logic value of“1”. When the voltage read from the memory cell is greater than 2.5 V and less than 3.5 V, it may be determined that the data stored in the memory cell has a logic value of “0”. The data stored in the memory cell may be classified depending on the difference between memory cell currents/voltages during the reading operations.

Meanwhile, a multi-bit cell (MLC) memory device that may store two or more bits of data in a single memory cell has been proposed in response to a need for higher integration of memory. The MLC memory device may also be referred to as a multi-bit cell (MBC) memory. However, as the number of bits stored in the single memory cell increases, reliability may deteriorate and the read-failure rate may increase. To program “m” bits in a single memory cell, any one of 2′ threshold voltages may be required to be formed in the memory cell. Due to the minute electrical characteristic difference between memory cells, threshold voltages of memory cells with the same data programmed may form a distribution within a predetermined range. A single threshold voltage distribution may correspond to each of the 2^{m} data values that can be generated according to the “m” bits.

However, since the voltage window of a memory may be limited, the distance between 2^{m} distributions of threshold voltage between adjacent bits may decrease as “m” increases, which may cause overlapping of the distributions. If the distributions overlap with each other, the read failure rate may increase.

Also, when data stored in the memory cell is maintained for a long period of time, distribution areas may overlap with each other due to factors affecting the reliability of the memory device whereby an error may occur to obstruct a state of information stored in a cell from being accurately read.

### SUMMARY

According to example embodiments, an apparatus may include a memory device. The memory device may include a memory cell array, a programming unit and a program level stabilization unit. The memory cell array may include a plurality of multi-level cells. The programming unit may be configured to program a first data page in the plurality of multi-level cells and to program a second data page in the plurality of multi-level cells having the programmed first data page. The program level stabilization unit may be configured to stabilize a program level of at least one of the first data page and the second data page.

### BRIEF DESCRIPTION OF THE DRAWINGS

The above and other features and advantages will become more apparent by describing in detail example embodiments thereof with reference to the attached drawings in which:

FIG. 1 is a block diagram illustrating a configuration of a memory device according to example embodiments;

FIG. 2 illustrates an example for describing an operation of a memory device according to example embodiments;

FIG. 3 illustrates another example for describing an operation of a memory device according to example embodiments;

FIG. 4 is a flowchart illustrating a memory programming method according to example embodiments; and

FIG. 5 is another flowchart illustrating a memory programming method according to example embodiments.

### DETAILED DESCRIPTION OF EMBODIMENTS

Example embodiments will now be described more fully with reference to the accompanying drawings. Embodiments, however, may be embodied in many different forms and should not be construed as being limited to example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

When it is determined that a detailed description related to a related known function or configuration may make the purpose of example embodiments unnecessarily ambiguous, the detailed description thereof will be omitted. Also, terms used herein are defined to appropriately describe the exemplary embodiments and thus may be changed depending on a user, the intent of an operator, or a custom. Accordingly, the terms must be defined based on the following overall description within this specification.

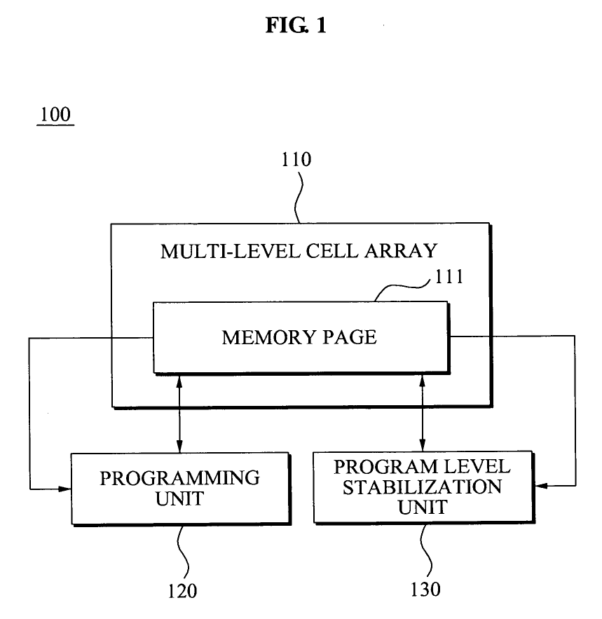

FIG. 1 is a block diagram illustrating a configuration of a memory device 100 according to example embodiments.

Referring to FIG. 1, the memory device 100 may include a multi-level cell array 110, a programming unit 120, and a program level stabilization unit 130.

The multi-level cell array 110 may include a plurality of multi-level cells. A process of storing data in a multi-level cell of a non-volatile memory such as, a flash memory, electrically erasable programmable read only memory (EEPROM), and the like, may be referred to as a programming process and may also be a process of changing a threshold voltage of the multi-level cell.

The process of programming data in the multi-level cell of the volatile memory may be performed using mechanism such as a Fowler-Nordheim (F-N) tunneling, a hot carrier effect, and the like. The F-N tunneling may change the threshold voltage of the multi-level cell. A single bit cell may have a low threshold voltage level or a high threshold voltage level. The single bit cell may express data of “0” or “1” using two threshold voltage levels.

In the case of a Charge Trap Flash (CTF) memory device, the multi-level cell array 110 may include an insulating layer including a charge trap site. The charge trap site may trap charges.

The programming unit 120 may change a threshold of each of the multi-level cells to thereby program data in each of the multi-level cells. When the multi-level cell stores m-bit data, the threshold voltage of the multi-level cell may be any one of 2^{m} voltage levels.

A process of programming, by the programming unit 120, data in a multi-level cell may require a relatively longer period of time than a process of reading, by the memory device 100, the data stored in the multi-level cell. In order to reduce a total programming time, the programming unit 120 may simultaneously program data in a plurality of multi-level cells.

Herein, a set of simultaneously programmed multi-level cells may be referred to as a memory page 111. The memory page 111 may be a set of multi-level cells that are simultaneously programmed by the programming unit 120. When each multi-level cell of the memory page stores m-bit data, the memory page 111 may store m data pages.

The programming unit 120 may program a first data page in the plurality of multi-level cells and program a second data page in the plurality of multi-level cells having the programmed first data page.

According to example embodiments, the programming unit 120 may perform a first page programming operation to thereby program a most significant bit (MSB) in the multi-level cells of the memory page 111. In this instance, a set of MSBs programmed in the multi-level cells of the memory page 111 may be referred to as a first data page.

The programming unit 120 may perform a second page programming operation to thereby program a second bit in the multi-level cells of the memory page 111. In this instance, a set of second bits programmed in the multi-level cells of the memory page 111 may be referred to as a second data page.

The programming unit 120 may perform an m^{th} page programming operation to thereby program a least significant bit (LSB) in the multi-level cells of the memory page 111. In this instance, a set of LSBs programmed in the multi-level cells of the memory page 111 may be referred to as an m^{th} data page.

The program level stabilization unit 130 may stabilize a program level of the first data page, the second data page, or the m^{th} data page. The program level may denote a state where the first data page, the second data page, or the m^{th} data page is programmed.

According to example embodiments, the program level stabilization unit 130 may stabilize a first program level of the first data page, a second program level of the second data page, or an m^{th} program level of the m^{th} data page, based on the change in a threshold voltage of the first data page, the second data page, or the m^{th} data page.

According to example embodiments, the program level stabilization unit 130 may stabilize the threshold voltage distribution of the multi-level cells.

The change in the threshold voltage may be caused by recombination of electrons and holes existing in the plurality of multi-level cells.

According to example embodiments, the programming unit 120 may reprogram, using the program level stabilization unit 130, the first data page corresponding to the stabilized first program level, the second data page corresponding to the stabilized second program level, or the m^{th} data page corresponding to the stabilized m^{th} program level.

According to example embodiments, the program level stabilization unit 130 may recombine the electron and the hole existing in the plurality of multi-level cells corresponding to the first data page, the second data page, or the m^{th} data page.

According to example embodiments, after the programming unit 120 programs the first data page, the program level stabilization unit 130 may stabilize the first program level. Next, after the program level stabilization unit 130 stabilizes the first program level, the programming unit 120 may program the second data page corresponding to the second program level based on the stabilized first program level.

In this case, in order to reduce the total programming time, the programming unit 120 may program the second data page corresponding to the second program level while simultaneously reprogramming the first data page corresponding to the stabilized first program level.

According to example embodiments, after the programming unit 120 programs the first data page and the second data page, the program level stabilization unit 130 may stabilize the first program level and the second program level.

In this case, according to example embodiments, the programming unit 120 may reprogram the first data page and the second data page based on the stabilized first program level and the second program level. In order to reduce the total programming time, the programming unit 120 may simultaneously reprogram the first data page and the second data page in the plurality of multi-level cells.

According to example embodiments, the memory device 100 may be a CTF memory device.

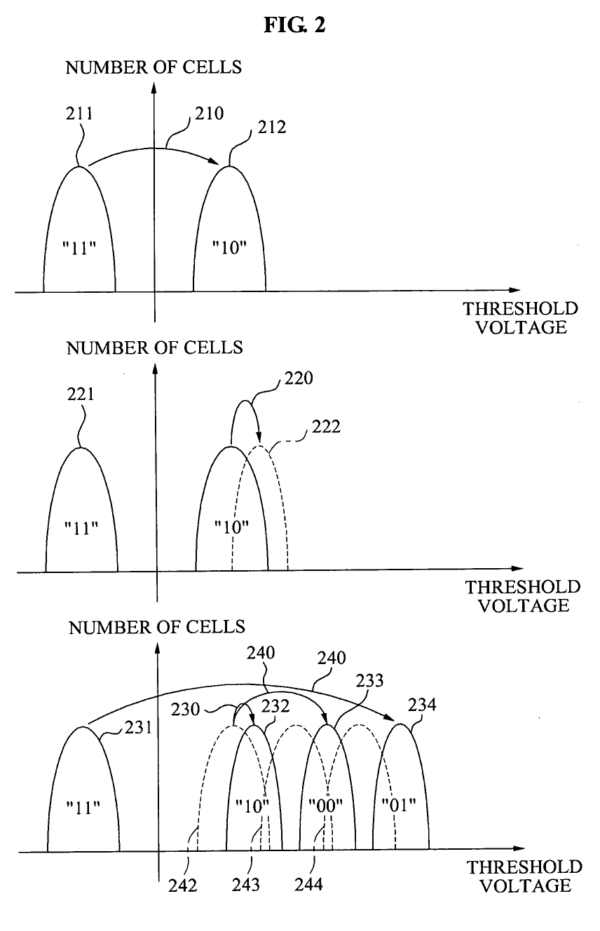

For example, the memory device 100 may inhibit the change in the threshold voltage, which may occur when maintaining data for a long period of time due to the structural characteristic of the memory cell, to thereby improve reliability of the memory device 100. Hereinafter, an operation of the memory device 100 according to example embodiments will be described in detail with reference to FIG. 2.

FIG. 2 illustrates an example for describing an operation of a memory device according to example embodiments.

Referring to FIG. 2, a horizontal axis denotes a threshold voltage and a vertical axis denotes a number of multi-level cells corresponding to the threshold voltage. FIG. 2 shows an example of a programming process.

A threshold voltage distribution of the multi-level cells may be represented by the number of multi-level cells corresponding to the threshold voltage.

Since the electrical characteristic of each multi-level cell may be minutely different, the threshold voltage of multi-level cells may form a distribution with a predetermined range. Multi-level cells storing data “11” may form a distribution 211, 221, or 231.

Multi-level cells storing data “10” may form a distribution 212, 222, or 232.

Multi-level cells storing data “00” may form a distribution 233.

Multi-level cells storing data “01” may form a distribution 234.

Generally, when a multi-level cell may have any one of 2^{m} threshold voltage levels, the multi-level cell may store a maximum of m bits of data. The m-bit data stored in the multi-level cell may be sorted in an order from an MSB to an LSB.

When the memory device 100 is a CFT memory device, it may be assumed that the distributions 231, 232, 233, and 234 are formed to have a predetermined threshold voltage distribution by injecting a predetermined amount of electrons in the distribution 211. In this instance, the distribution 211 may be in an erase state. In this case, although the predetermined amount of electrons are injected into an insulating layer including a charge trap site through a programming operation, a portion of holes existing in the distribution 211 of the erase state may still remain in the insulating layer including the charge trap site.

The number of holes remaining in each programming state may accumulatively increase as the number of programming and erase operations increases. When the programming operation is completed by forming the distributions 231, 232, 233, and 234 and in this state, data is maintained for a long period of time, the electrons and holes existing in the insulating layer including the charge trap site may be recombined and thereby disappear.

There may be some difference between a threshold voltage distribution of each programming state after the programming process is completed through the above recombination process and a threshold voltage distribution when maintaining data for the long period of time. For example, although the distributions 231, 232, 233, or 234 may be formed with a predetermined threshold voltage distribution after the programming process is completed, the threshold voltage distribution may change from the distribution 232 to the distribution 242, from the distribution 233 to the distribution 243, or from the distribution 234 to the distribution 244 when maintaining the data for the long period of time.

Due to the change in the threshold voltage distribution, a distance between the 2^{m} distributions of adjacent bits may be reduced. When the inter-distribution distance is further reduced, the distributions may be overlap with each other. In this case, a read failure rate may increase. The number of holes may accumulatively increase as the number of times that the programming and erase processes are performed increases. The change in the threshold voltage distribution may further increase due to recombination of electrons and holes.

According to example embodiments, the memory device 100 may stabilize a program level of a first data page, a second data page, or an m^{th} data page. Also, the memory device 100 may stabilize a first program level of the first data page, a second program level of the second data page, or an m^{th} program level of the m^{th} data page based on the first data page, the second data page, or the m^{th} data page. According to example embodiments, the memory device 100 may program the first data page and then may stabilize the first program level. After stabilizing the first program level, the memory device 100 may program the second data page corresponding to the second program level based on the stabilized first program level.

Also, the memory device 100 may program the second data page corresponding to the second program level and at the same time, reprogram the first data page corresponding to the stabilized first program level.

Referring to FIG. 2, an arrow indicator 210 denotes a state where the memory device 100 performs a programming operation of the first data page for multi-level cells of the distribution 211 to thereby form the distribution 212.

After performing the programming operation of the first data page, a threshold voltage of multi-level cells of the multi-level array 110 may correspond to the distribution 212.

An arrow indicator 220 denotes a state where the memory device 100 performs the programming operation of the first data page and then stabilizes the first program level of the first data page. The memory device 100 may stabilize the first program level to thereby form the distribution 222.

According to example embodiments, the memory device 100 may stabilize the first program level based on the change in the threshold voltage of the first data page that may occur by recombination of electrons and holes existing in the plurality of multi-level cells.

According to example embodiments, the memory device 100 may recombine electrons and holes existing in the plurality of multi-level cells corresponding to the first data page to thereby stabilize the first program level. Through this, the memory device 100 may stabilize the threshold voltage distribution.

After stabilizing the first program level, the threshold voltage of multi-level cells of the multi-level cell array 110 may correspond to the distribution 222.

An arrow indicator 240 denotes a state where the memory device 100 stabilizes the first program level and then performs a programming operation of the second data page based on the stabilized first program level to thereby form the distributions 233 and 234.

After performing the programming operation of the second data page, the threshold voltage of multi-level cells of the multi-level cell array 110 may correspond to the distributions 233 and 234.

An arrow indicator 230 denotes a state where the memory device 100 simultaneously performs the programming operation of the second data page corresponding to the second program level and the reprogramming operation of the first data page corresponding to the stabilized first program level to thereby form the distribution 232.

After programming the reprogramming operation of the first data page, the threshold voltage of multi-level cells of the multi-level cell array 110 may correspond to the distribution 232.

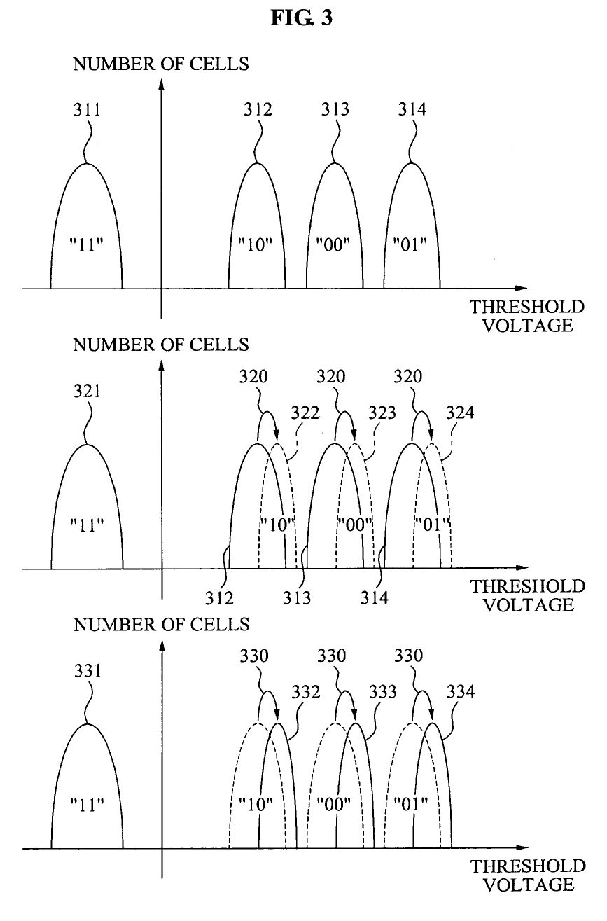

Through this, the memory device 100 may inhibit the change in the threshold voltage, which may occur when maintaining data for a long period of time due to the structural characteristic of the memory cell, to thereby improve reliability of the memory device 100. Hereinafter, an operation of the memory device 100 according to other example embodiments will be described in detail with reference to FIG. 3.

FIG. 3 illustrates another example for describing an operation of a memory device according to example embodiments.

A distribution of threshold voltage of multi-level cells may be represented by a number of multi-level cells corresponding to the threshold voltage.

Since the electrical characteristic of each multi-level cell may be minutely different, the threshold voltage of multi-level cells may form a distribution with a predetermined range.

Multi-level cells storing data “11” may form a distribution 311, 321, or 331.

Multi-level cells storing data “10” may form a distribution 312, 322, or 332.

Multi-level cells storing data “00” may form a distribution 313, 323, or 333.

Multi-level cells storing data “01” may form a distribution 314, 324, or 334.

When the memory device 100 is a CTF memory device, the memory device 100 may perform a programming operation of a first data page and a programming operation of a second data page in the distribution 311 that is in an erase state to thereby form the distributions 311, 312, 313, and 314 with a predetermined threshold voltage distribution.

As described above, there may be some difference between a threshold voltage distribution of each programming state after the programming process is completed through a recombination process of electrons and holes and a threshold voltage distribution when maintaining data for a long period of time. For example, although the distributions 311, 312, 313, and 314 with a predetermined threshold voltage distribution are formed after the programming process is completed, the threshold voltage distribution of the distributions 311, 312, 313, and 314 may change when maintaining the data for the long period of time.

Due to the change in the threshold voltage distribution, a distance between 2^{m} distributions of adjacent bits may be reduced. When the inter-distribution distance is further reduced, the distributions may be overlapped with each other. In this case, a read failure rate may increase. The number of holes may accumulatively increase as the number of times that the programming and erase process is performed increases. The change in the threshold voltage distribution may further increase due to recombination of electrons and holes.

According to example embodiments, the memory device 100 may stabilize a program level of the first data page or the second data page. According to example embodiments, the memory device 100 may stabilize a first program level of the first data page or a second program level of the second data page based on the change in a threshold voltage of the first data page or the second data page.

According to example embodiments, the memory device 100 may program the first data page and the second data page and then stabilize the first program level and the second program level.

According to example embodiments, the memory device 100 may reprogram the first data page and the second data page based on the stabilized first program level and the stabilized second program level.

Referring again to FIG. 3, the memory device 100 may perform the programming operation of the first data page and the programming operation of the second data page for the distribution 311 to thereby form the distributions 311, 312, 313, and 314.

After performing the programming operation of the first data page and the programming operation of the second data page, a threshold voltage of multi-level cells of the multi-level cell array 110 may correspond to the distributions 311, 312, 313, and 314.

An arrow indicator 320 denotes a state where the memory device 100 programs the first data page and the second data page and then stabilizes the first program level of the first data page and the second program level of the second data page.

The memory device 100 may stabilize the first program level and the second program level to form the distributions 321, 322, 323, and 324.

According to example embodiments, the memory device 100 may stabilize the first program level and the second program level based on the change in the threshold voltage of the first data page and the second data page that may be caused by recombination of electrons and holes existing in the plurality of multi-level cells.

According to example embodiments, the memory device 100 may recombine electrons and holes existing in the plurality of multi-level cells corresponding to the first data page or the second data page to thereby stabilize the first program level and the second program level. Through this, the memory device 100 may stabilize the threshold voltage distribution.

After stabilizing the first program level and the second program level, the threshold voltage of multi-level cells of the multi-level cell array 110 may correspond to the distributions 321, 322, 323, and 324.

An arrow indicator 330 denotes a state where the memory device 100 stabilizes the first program level and the second program level and then performs a reprogramming operation of the first data page and a reprogramming operation of the second data page based on the stabilized first program level and the second program level, respectively, to thereby form the distributions 331, 331, 333, and 334.

After performing the reprogramming operation of the first data page and the reprogramming operation of the second data page, the threshold voltage of multi-level cells of the multi-level cell array 110 may correspond to the distributions 331, 332, 333, and 334.

Through this, the memory device 100 may inhibit the change of the threshold voltage, which may occur when maintaining data for a long period of time due to the structural characteristic of the memory cell, to thereby improve reliability of the memory device 100. Hereinafter, a data programming method that may be performed in a memory device according to example embodiments will be described in detail.

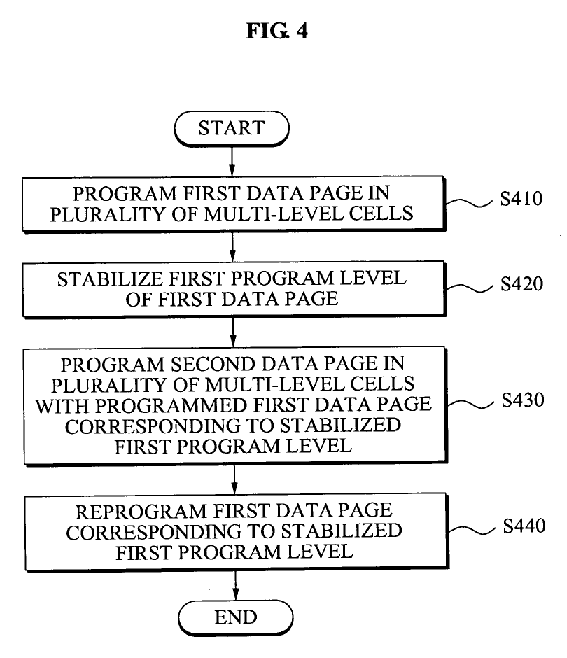

FIG. 4 is a flowchart illustrating a memory programming method according to example embodiments.

In operation S410, the memory programming method may program a first data page in a plurality of multi-level cells.

In operation S420, the memory programming method may stabilize a first program level of the first data page.

According to example embodiments, the memory programming method may stabilize the first program level based on the change in a threshold voltage of the first data page that may be caused by recombination of electrons and holes existing in the plurality of multi-level cells.

According to example embodiments, the memory programming method may recombine electrons and holes existing in the plurality of multi-level cells corresponding to the first data page to thereby stabilize the first program level. Through this, the memory programming method may stabilize the threshold voltage distribution.

In operation S430, the memory programming method may program a second data page in the plurality of multi-level cells with the programmed first data page corresponding to the stabilized first program level. For example, the memory programming method may perform a programming operation of the second data page based on the stabilized first program level.

In operation S440, the memory programming method may reprogram the first data page corresponding to the stabilized first program level.

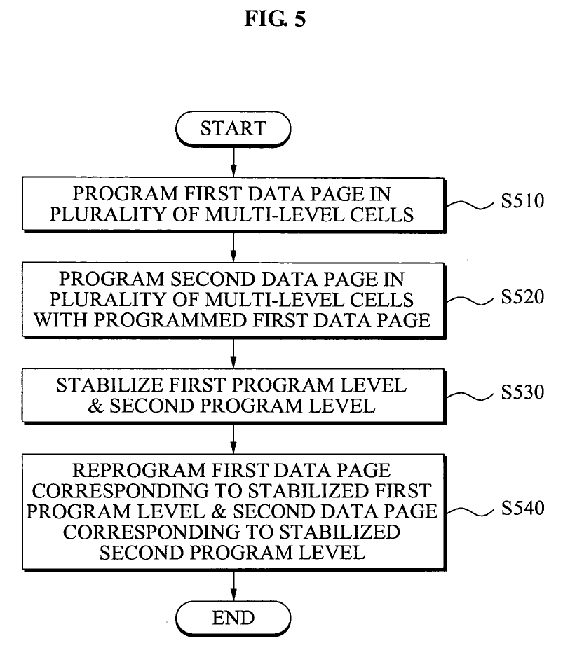

FIG. 5 is another flowchart illustrating a memory programming method according to example embodiments.

In operation S510, the memory programming method may program a first data page in a plurality of multi-level cells.

In operation S520, the memory programming method may program a second data page in the plurality of multi-level cells with the programmed first data page.

In operation S530, the memory programming method may stabilize a first program level of the first data page and a second program level of the second data page.

According to example embodiments, the memory programming method may stabilize the first program level of the first data page or the second program level of the second data page based on the change in the threshold voltage of the first data page or the second data page.

In operation S540, the memory programming method may reprogram the first data page corresponding to the stabilized first program level and reprogram the second data page corresponding to the stabilized second program level.

According to example embodiments, it may possible to inhibit the change in the threshold voltage, which may occur when maintaining data for a long period of time due to the structural characteristic of the memory cell and thereby improve reliability of a memory device.

Example embodiments may be applicable to memory devices that change a threshold voltage of a memory cell to thereby store data, for example, a flash memory, an EEPROM, and the like.

The memory programming method according to example embodiments may be recorded in computer-readable media including program instructions to implement various operations embodied by a computer. The media may also include, alone or in combination with the program instructions, data files, data structures, and/or the like. The media and program instructions may be those especially designed and constructed for the purposes of example embodiments, or they may be of the kind well-known and available to those having skill in the computer software arts. Examples of computer-readable media include magnetic media such as hard disks, floppy disks, and magnetic tape; optical media such as CD ROM disks and DVD; magneto-optical media such as optical disks; and hardware devices that are especially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of example embodiments, or vice versa.

Flash memory devices and/or memory controllers according to example embodiments may be embodied using various types of packages. For example, the flash memory devices and/or memory controllers may be embodied using packages such as Package on Packages (PoPs), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Quad Flatpack (QFP), Small Outline Integrated Circuit (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

The flash memory devices and/or the memory controllers may constitute memory cards. In example embodiments, the memory controllers may be constructed to communicate with an external device for example, a host using any one of various types of protocols such as a Universal Serial Bus (USB), a Multi Media Card (MMC), a Peripheral Component Interconnect-Express (PCI-E), Serial Advanced Technology Attachment (SATA), Parallel ATA (PATA), Small Computer. System Interface (SCSI), Enhanced Small Device Interface (ESDI), and Integrated Drive Electronics (IDE).

The flash memory devices may be non-volatile memory devices that may maintain stored data even when power is cut off. According to an increase in the use of mobile devices such as a cellular phone, a personal digital assistant (PDA), a digital camera, a portable game console, and an MP3 player, the flash memory devices may be more widely used as data storage and code storage. The flash memory devices may be used in home applications such as a high definition television (HDTV), a digital video disk (DVD), a router, and a Global Positioning System (GPS).

A computing system, according to example embodiments, may include a microprocessor that may be electrically connected with a bus, a user interface, a modem such as a baseband chipset, a memory controller, and a flash memory device. The flash memory device may store N-bit data via the memory controller. The N-bit data may be processed or will be processed by the microprocessor and N may be 1 or an integer greater than 1. When the computing system is a mobile apparatus, a battery may be additionally provided to supply operation voltage to the computing system.

It will be apparent to those of ordinary skill in the art that the computing system according to example embodiments may further include an application chipset, a camera image processor (CIS), a mobile Dynamic Random Access Memory (DRAM), and the like. The memory controller and the flash memory device may constitute a solid state drive/disk (SSD) that uses a non-volatile memory to store data.

While example embodiments have been particularly shown and described, it will be understood by those of ordinary skill in the art that various changes in form and details may be made therein without departing from the spirit and scope of example embodiments as defined by the following claims.

What is claimed is:

1. A memory device comprising:
a memory cell array including a plurality of multi-level cells;
a programming unit configured to program a first data page in the plurality of multi-level cells and to program a second data page in the plurality of multi-level cells having the programmed first data page; and
a program level stabilization unit configured to stabilize a program level of at least one of the first data page and the second data page.

2. The memory device of claim 1, wherein the program level stabilization unit stabilizes at least one of a first program level of the first data page and a second program level of the second data page based on the change in a threshold voltage of the first data page or the second data page.

3. The memory device of claim 2, wherein the programming unit reprograms at least one of the first data page corresponding to the stabilized first program level and the second data page corresponding to the stabilized second program level.

4. The memory device of claim 2, wherein the change in the threshold voltage is based on recombination of electrons and holes existing in the plurality of multi-level cells.

5. The memory device of claim 4, wherein the program level stabilization unit recombines electrons and holes existing in the plurality of multi-level cells corresponding to at least one of the first data page and the second data page.

6. The memory device of claim 5, wherein the programming unit reprograms at least one of the first data page corresponding to the stabilized first program level and the second data page corresponding to the stabilized second program level.

7. The memory device of claim 1, wherein the programming unit reprograms at least one of the first data page corresponding to the stabilized first program level and the second data page corresponding to the stabilized second program level.

8. The memory device of claim 1, wherein the program level stabilization unit recombines electrons and holes existing in the plurality of multi-level cells corresponding to at least one of the first data page and the second data page.

9. The memory device of claim 1, wherein the program level stabilization unit stabilizes a threshold voltage distribution of the plurality of multi-level cells.

10. The memory device of claim 1, wherein the program level stabilization unit stabilizes the first program level after the programming unit programs the first data page.

11. The memory device of claim 10, wherein the programming unit programs the second data page corresponding to the second program level based on the stabilized first program level after the program level stabilization unit stabilizes the first program level.

12. The memory device of claim 11, wherein the programming unit reprograms the first data page corresponding to the stabilized first program level and simultaneously programs the second data page corresponding to the second program level.

13. The memory device of claim 11, wherein the programming unit reprograms the first data page corresponding to the stabilized first program level after the programming unit programs the second data page corresponding to the second program level.

14. The memory device of claim 1, wherein the program level stabilization unit stabilizes the first program level and the second program level after the programming unit programs the first data page and the second data page.

15. The memory device of claim 14, wherein the programming unit reprograms the first data page and the second data page based on the stabilized first program level and the stabilized second program level.

16. The memory device of claim 14, wherein the programming unit programs each of the first data page and the second data page such that the set of multi-level cells are simultaneously programmed by the programming unit.

17. The memory device of claim 1, wherein the programming unit programs the first data page before the second data page.

18. The memory device of claim 17, wherein the programming unit programs the first data page such that a most significant bit (MSB) in the multi-level cells is programmed and programs the second data page such that a least significant bit (LSB) in the multi-level cells is programmed.
